(19) United States
(12) Patent Application Publication
(10) Pub. No.: US 2026/0025916 A1
(43) Pub. Date: Jan. 22, 2026

(54) SIDEWALL SHIELDING OF PRINTED WIRING SUBSTRATES

(71) Applicant: International Business Machines Corporation, Armonk, NY (US)

(72) Inventors: Matthew Doyle, Chatfield, MN (US); Samuel R. Connor, Apex, NC (US); Matteo Cocchini, New York, NY (US); Layne A. Berge, Windsor, CO (US)

(21) Appl. No.: 18/779,451

(22) Filed: Jul. 22, 2024

(51) Int. Cl. H05K 1/02; H01Q 13/10; H05K 1/18; H05K 3/30; H05K 3/46

(52) U.S. Cl. CPC H05K 1/0298; H05K 1/181; H05K 3/303; H05K 3/46; H01Q 13/10; H05K 2201/1003

(57) ABSTRACT

A printed wiring substrate assembly is provided and includes a substrate, a foil and first and second attachments. The substrate includes electrical traces, an upper surface, a lower surface opposite the upper surface and a substrate edge surface extending between corresponding respective edges of the upper and lower surfaces. The foil includes a first foil end, a second foil end opposite the first foil end and an elongate foil portion extending between the first and second foil ends. The first and second foil ends are attached to the corresponding respective edges of the upper and lower surfaces at the first and second attachments, respectively, with the elongate foil portion displaced from the substrate edge surface.

### BACKGROUND

The present disclosure generally relates to fabrication methods and resulting structures for printed wiring substrates. More specifically, the present disclosure relates to electromagnetic interference (EMI) sidewall shielding for printed wiring substrates.

Printed wiring substrates, such as printed circuit boards (PCBs), are structures having a rigid, non-conductive substrate layer or a laminate of multiple substrate layers and conductive pathways for routing electronic signals and electric power to a circuit assembly that is typically mounted on the PCB surface. In a given PCB, the conductive pathways may form a circuit assembly, including various electrical and electronic components and one or more devices, and the conductive pathways may be located along the PCB surface or may be embedded in or on layers within a multi-layer substrate. Multiple PCBs can be bonded together, and the conductive pathways may be electrically connected using through-hole vias.

### SUMMARY

A printed wiring substrate assembly is provided and includes a substrate, a foil and first and second attachments. The substrate includes electrical traces, an upper surface, a lower surface opposite the upper surface and a substrate edge surface extending between corresponding respective edges of the upper and lower surfaces. The foil includes a first foil end, a second foil end opposite the first foil end and an elongate foil portion extending between the first and second foil ends. The first and second foil ends are attached to the corresponding respective edges of the upper and lower surfaces at the first and second attachments, respectively, with the elongate foil portion displaced from the substrate edge surface. In one or more additional or alternative embodiments, the foil provides for continuous EMI shielding that does not require post-processing operations.

According to an aspect of the disclosure, a printed wiring substrate assembly is provided and includes a substrate, first and second foils and first and second attachments. The substrate includes electrical traces, an upper surface, a lower surface opposite the upper surface and first and second substrate edge surfaces forming a corner and respectively extending between corresponding respective edges of the upper and lower surfaces. The first and second foils are respectively associated with the first and second substrate edges and each includes a first foil end, a second foil end opposite the first foil end and an elongate foil portion extending between the first and second foil ends. The first and second attachments are provided for each of the first and second foils where the respective first and second foil ends are attached to the corresponding respective edges of the upper and lower surfaces, respectively, with the respective elongate foil portions displaced from the first and second substrate edge surfaces. In one or more additional or alternative embodiments, the foil provides for continuous EMI shielding that does not require post-processing operations.

According to an aspect of the disclosure, a method of fabricating a printed wiring substrate assembly is provided and includes forming a substrate, at least one of disposing electrical traces on an upper surface of the substrate, disposing electrical traces on a lower surface of the substrate and embedding electrical traces within the substrate, providing a foil including a first foil end, a second foil end opposite the first foil end and an elongate foil portion extending between the first and second foil ends and attaching the first and second foil ends to corresponding respective edges of the upper and lower surfaces, respectively, with the elongate foil portion displaced from a substrate edge surface extending between the corresponding respective edges of the upper and lower surfaces. In one or more additional or alternative embodiments, the foil provides for continuous EMI shielding that does not require post-processing operations.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a schematic graphical illustration of a formation of a foil for EMI shielding of a printed wiring substrate and attachment of the foil to the printed wiring substrate in accordance with one or more embodiments;

FIG. 2A is a top-down view of the printed wiring substrate and the foil of FIG. 1 in accordance with one or more embodiments;

FIG. 2B is an enlarged top-down view of the printed wiring substrate and the foil of FIG. 1 taken from the portion of FIG. 2A identified by dashed line 2B in accordance with one or more embodiments;

FIG. 3 is a side view of the printed wiring substrate and the foil of FIG. 1 taken along line 3-3 of FIG. 2A in accordance with one or more embodiments;

FIG. 4 is a side schematic illustration of the foil of FIG. 1 formed of metallic material in accordance with one or more embodiments;

FIG. 5 is a side schematic illustration of the foil of FIG. 1 formed as a copper clad plane pair in accordance with one or more embodiments;

FIG. 6 is a schematic perspective view of a foil with I/O paths and/or power paths for EMI shielding of a printed wiring substrate in accordance with one or more embodiments;

FIG. 7 is a schematic graphical illustration of a formation of a foil with a component on an underside thereof for EMI shielding of a printed wiring substrate and attachment of the foil to the printed wiring substrate in accordance with one or more embodiments; and

FIG. 8 is a flow diagram illustrating a method of fabricating a printed wiring substrate assembly in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

A printed wiring substrate assembly is provided and includes a substrate, a foil and first and second attachments. The substrate includes electrical traces, an upper surface, a lower surface opposite the upper surface and a substrate edge surface extending between corresponding respective edges of the upper and lower surfaces. The foil includes a first foil end, a second foil end opposite the first foil end and an elongate foil portion extending between the first and second foil ends. The first and second foil ends are attached to the corresponding respective edges of the upper and lower surfaces at the first and second attachments, respectively, with the elongate foil portion displaced from the substrate edge surface. In one or more additional or alternative embodiments, the foil provides for continuous EMI shielding that does not require post-processing operations.

In accordance with one or more additional or alternative embodiments, the substrate is at least one of a single-layer printed circuit board (PCB) and a multi-layer PCB including multiple PCB layers laminated together and the electrical traces are at least one of disposed on the upper surface, disposed on the lower surface and embedded within the substrate with the foil being compatible with each option.

In accordance with one or more additional or alternative embodiments, the elongate foil portion is displaced from the substrate edge surface by a distance that is a fraction of a thickness of the substrate such that the foil is relatively closely held to the edge surface.

In accordance with one or more additional or alternative embodiments, the foil is continuous along an entirety of the substrate edge surface and does not include open spaces or tabs and avoids or reduces peeling.

In accordance with one or more additional or alternative embodiments, the foil is formed to define at least one of one or more slots for slot antennae, one or more holes for moisture, chemical and/or gaseous outflows and one or more embossments for quick response (QR) coding and/or barcoding such that the printed wiring substrate assembly is not restricted in applications.

In accordance with one or more additional or alternative embodiments, the foil includes at least one of metallic material and a copper clad plane pair which allows the foil to support one or more features, such as electric traces.

In accordance with one or more additional or alternative embodiments, the first and second attachments include at least one of conductive adhesive, solder, mounting screws and clamps which allows the first and second attachments to be formed in various manners.

In accordance with one or more additional or alternative embodiments, the foil includes at least one of input/output (I/O) traces and power lines which increases the overall utility of the printed wiring substrate assembly.

In accordance with one or more additional or alternative embodiments, the printed wiring substrate assembly further includes a component mounted to a surface of the elongate foil portion facing the substrate edge surface and the component includes at least one of a direct current (DC) blocking cap, an oscillator and a wire-wound inductor which at least provides for increased EMI shielding.

According to an aspect of the disclosure, a printed wiring substrate assembly is provided and includes a substrate, first and second foils and first and second attachments. The substrate includes electrical traces, an upper surface, a lower surface opposite the upper surface and first and second substrate edge surfaces forming a corner and respectively extending between corresponding respective edges of the upper and lower surfaces. The first and second foils are respectively associated with the first and second substrate edges and each includes a first foil end, a second foil end opposite the first foil end and an elongate foil portion extending between the first and second foil ends. The first and second attachments are provided for each of the first and second foils where the respective first and second foil ends are attached to the corresponding respective edges of the upper and lower surfaces, respectively, with the respective elongate foil portions displaced from the first and second substrate edge surfaces. In one or more additional or alternative embodiments, the foil provides for continuous EMI shielding that does not require post-processing operations.

In accordance with one or more additional or alternative embodiments, the substrate is at least one of a single-layer printed circuit board (PCB) and a multi-layer PCB including multiple PCB layers laminated together and the electrical traces are at least one of disposed on the upper surface, disposed on the lower surface and embedded within the substrate with the foil being compatible with each option.

In accordance with one or more additional or alternative embodiments, the respective elongate foil portions are displaced from the first and second substrate edge surfaces by distances that are fractions of a thickness of the substrate such that the foil is relatively closely held to the edge surface.

In accordance with one or more additional or alternative embodiments, the first and second foils are each continuous along respective entireties of the first and second substrate edge surfaces and form a gap between proximal sides at the corner and does not include open spaces or tabs and avoids or reduces peeling.

In accordance with one or more additional or alternative embodiments, the foil is formed to define at least one of one or more slots for slot antennae, one or more holes for moisture, chemical and/or gaseous outflows and one or more embossments for quick response (QR) coding and/or barcoding such that the printed wiring substrate assembly is not restricted in applications.

In accordance with one or more additional or alternative embodiments, each of the first and second foils includes at least one of metallic material and a copper clad plane pair which allows the foil to support one or more features, such as electric traces.

In accordance with one or more additional or alternative embodiments, each of the first and second attachments for each of the first and second foils includes at least one of conductive adhesive, solder, mounting screws and clamps which allows the first and second attachments to be formed in various manners.

In accordance with one or more additional or alternative embodiments, each of the first and second foils includes at least one of input/output (I/O) traces and power lines which increases the overall utility of the printed wiring substrate assembly.

In accordance with one or more additional or alternative embodiments, the printed wiring substrate assembly further includes components mounted to surfaces of the respective elongate foil portions facing the first and second substrate edge surfaces and each of the components includes at least one of a direct current (DC) blocking cap, an oscillator and a wire-wound inductor which at least provides for increased EMI shielding.

According to an aspect of the disclosure, a method of fabricating a printed wiring substrate assembly is provided and includes forming a substrate, at least one of disposing electrical traces on an upper surface of the substrate, disposing electrical traces on a lower surface of the substrate and embedding electrical traces within the substrate, providing a foil including a first foil end, a second foil end opposite the first foil end and an elongate foil portion extending between the first and second foil ends and attaching the first and second foil ends to corresponding respective edges of the upper and lower surfaces, respectively, with the elongate foil portion displaced from a substrate edge surface extending between the corresponding respective edges of the upper and lower surfaces. In one or more additional or alternative embodiments, the foil provides for continuous EMI shielding that does not require post-processing operations.

In accordance with one or more additional or alternative embodiments, the method further includes at least one of forming at least one of input/output (I/O) traces and power lines along the foil, etching at least one of one or more slots, one or more holes and one or more embossments into the foil and mounting a component to a surface of the elongate foil portion facing the substrate edge surface, the component including at least one of a direct current (DC) blocking cap, an oscillator and a wire-wound inductor so that the foil can provide for alternative configurations and structures For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, EMI is a persistent concern for PCBs and various types of shielding have been utilized to minimize EMI. For example, it has been found that, particularly with higher frequency interconnects, current communicated between two conductive layers in a PCB can effectively create a slot antenna that radiates noise both within and outside of a chassis within which the PCB is mounted. In some PCB designs, fences formed by grounded vias running along the edges of a PCB at regular intervals are used to reduce EMI emissions and susceptibility, although the use of increasingly higher signal frequencies can require smaller via spacings that can be problematic to achieve. In other PCB designs, ground edge plating may be used to interconnect ground planes within a PCB with a conductive material electroplated onto the edges of the PCB. Edge plating in this manner can be more effective at shielding EMI than fencing, but generally comes at a higher cost.

The higher costs of edge plating result from the fact that edge plating often requires additional substrate processing, handling and plating steps. Further, post-processing and assembly steps frequently result in mechanical and electrical damage to sidewall edge plating, further increasing costs by reducing yield and by introducing risks of field failures.

Turning now to an overview of the aspects of the disclosure, one or more embodiments of the disclosure address the above-described shortcomings of the prior art by providing EMI sidewall shielding of printed wiring substrates without the need for existing copper plating processes of substrate sidewalls. Portions of conductive planes (i.e., foils used in PCB manufacturing processes) are used to shield substrate sidewalls without the need for additional plating processes. The EMI sidewall shielding also allows for input/output (I/O) interconnects traversing same sidewall paths, which can be used in certain scenarios such as for lower-frequency, slow edge-rate I/O that is not a significant emissions or immunity risk.

The EMI sidewall shielding provides continuous shielding along a PCB edge and improved EMI performance without need for a routing operation prior to plating, which leads to lower cost manufacturing. The EMI sidewall shielding avoids manufacturing defects associated with routing processes (i.e., by cutting off “tabs”), enables routing I/O along PCB edges, avoids the use of vias for improved signal integrity and saves wiring channels for improved wire-ability due to reduced layout effort and lower crosstalk.

The above-described aspects of the disclosure address the shortcomings of the prior art by providing a printed wiring substrate assembly that includes a substrate, a foil and first and second attachments. The substrate includes electrical traces, an upper surface, a lower surface opposite the upper surface and a substrate edge surface extending between corresponding respective edges of the upper and lower surfaces. The foil includes a first foil end, a second foil end opposite the first foil end and an elongate foil portion extending between the first and second foil ends. The first and second attachments are provided where the first and second foil ends are attached to the corresponding respective edges of the upper and lower surfaces, respectively, with the elongate foil portion displaced from the substrate edge surface.

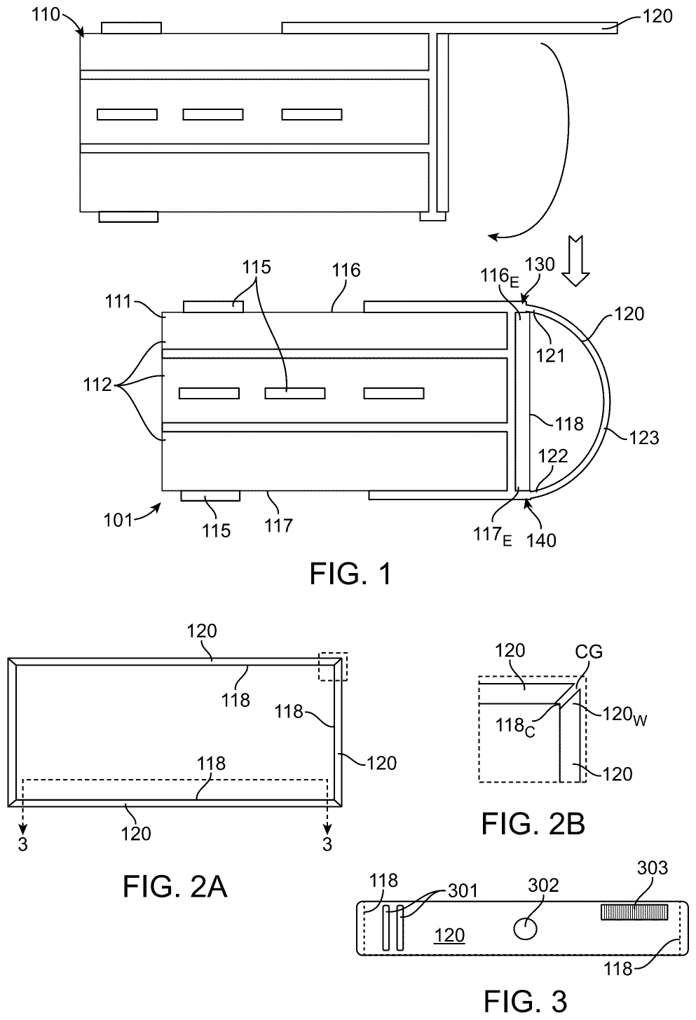

With reference to FIGS. 1, 2A, 2B and 3, a printed wiring substrate assembly 101 is provided and includes a substrate 110, which can be provided as any one or more of a PCB, a single-layer PCB and a multi-layer PCB, but which is illustrated in FIG. 1 for purposes of clarity and brevity as a multi-layer PCB 111 including multiple PCB layers 112 laminated together. The substrate 110 includes electrical traces 115, an upper surface 116, a lower surface 117 opposite the upper surface 116 and a substrate edge surface 118 extending between corresponding respective edges 116E and 117E of the upper and lower surfaces 116 and 117. The electrical traces 115 can be at least one or more of disposed on the upper surface 116, disposed on the lower surface 117 and embedded within the substrate 110 (i.e., embedded within the multiple PCB layers 112 and/or embedded between neighboring ones of the multiple PCB layers 112). The printed wiring assembly 101 further includes a foil 120, a first attachment section 130 and a second attachment section 140. The foil 120 includes a first foil end 121, a second foil end 122 opposite the first foil end 121 and an elongate foil portion 123 extending between the first and second foil ends 121 and 122. The first attachment section 130 is provided where the first foil end 121 is attached to the edge 116E of the upper surface 116. The second attachment section 140 is provided where the second foil end 122 is attached to the edge 117E of the lower surface 117. With the first foil end 121 attached to the edge 116E and with the second foil end 122 attached to the edge 117E, the elongate foil portion 123 is displaced from the substrate edge surface 118.

The foil 120 provides continuous EMI shielding along the substrate edge surface 118 and improved EMI performance without need for a routing operation prior to plating, which leads to lower cost manufacturing. The use of the foil 120 avoids manufacturing defects associated with routing processes (i.e., by cutting off “tabs”), enables routing of I/O paths along the foil 120 (see below), avoids the use of vias for improved signal integrity and saves wiring channels for improved wire-ability due to reduced layout effort and lower crosstalk.

In accordance with one or more embodiments, the first attachment section 130 and the second attachment section 140 can each include at least one of conductive adhesive, solder, mounting screws and clamps.

It is to be understood that, although FIG. 1 illustrates an arc of the elongate foil portion 123 with a significant displacement of the elongate foil portion 123 from the substrate edge surface 118, the illustration is not to scale. Rather, the elongate foil portion 123 is displaced from the substrate edge surface 118 by a small fraction of a thickness of the substrate 110 as long as the elongate foil portion 123 and the foil 120 in general is without kinks or folds with sharp angles. In an exemplary case, the substrate 110 can be about 50-60 mils thick and, in these or other exemplary cases, the elongate foil portion 123 can be displaced from the substrate edge surface 118 by a distance that is a small fraction of the 50-60 mil thickness of the substrate 110.

It is to be further understood that the substrate 110 can include multiple substrate edge portions 118 and that neighboring substrate edge portions 118 can form a corner 118c as shown in FIGS. 2A and 2B. In these or other cases, the printed wiring substrate assembly 101 can include multiple foils 120, with one or more foils 120 for each of the multiple substrate edge portions 118. Where neighboring substrate edge portions 118 form the corner 118c, the corresponding foils 120 can include wing sections 120w that each extend outwardly and at a diagonal from the corresponding one of the neighboring substrate edge portions 118. The wing sections 120w can terminate substantially closely to one another by may in certain cases form a corner gap CG, which is acceptable from an EMI shielding perspective provided the corner gap CG is limited to the corner 118c.

As shown in FIGS. 2A and 3, the foil 120 is continuous along an entirety of the substrate edge surface 118. This stands in contrast to conventional edge plating in which edge plating portions are intermittently removed from a PCB. In accordance with one or more embodiments, however, even with the foil 120 being continuous along the entirety of the substrate edge surface 118, the foil 120 can be formed to define at least one of one or more slots 301 to serve as antennae for radio frequency (RF) or other short-range wireless protocols, one or more holes 302 to enable moisture, chemical and/or gaseous outflows and one or more embossments 303 to enable the generation of quick response (QR) coding and/or barcoding. Where the foil 120 is formed to define the at least one of the one or more slots 301, the one or more holes 302 and the one or more embossments 303, the continuity of the foil 120 along the entirety of the substrate edge surface 118 is exhibited in the fact that at least some part of the foil 120 is present at the axial location of the at least one of the one or more slots 301, the one or more holes 302 and the one or more embossments 303.

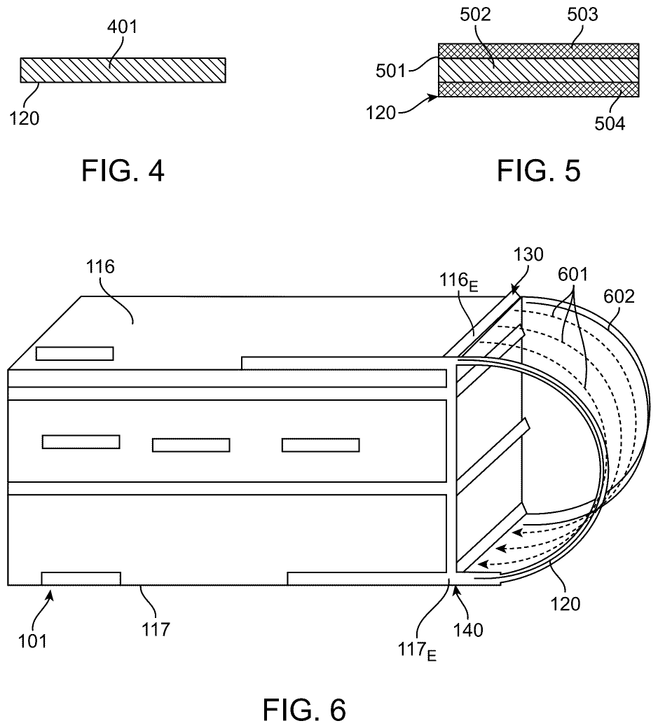

With continued reference to FIGS. 1, 2A, 2B and 3 and with additional reference to FIGS. 4 and 5, the foil 120 can include at least one of metallic material 401, such as only copper, and a copper clad plane pair 501 in which a copper sheet 502 is sandwiched between upper and lower dielectric sheets 503 and 504.

With continued reference to FIGS. 1, 2A, 2B and 3 and with additional reference to FIG. 6, the foil 120 can include at least one of input/output (I/O) traces 601 and power lines 602. In this way, the foil 120 can provide for continuous Emi shielding, EMI reduction as well as I/O pathways and/or power pathways between at least the upper surface 116 and the lower surface 117.

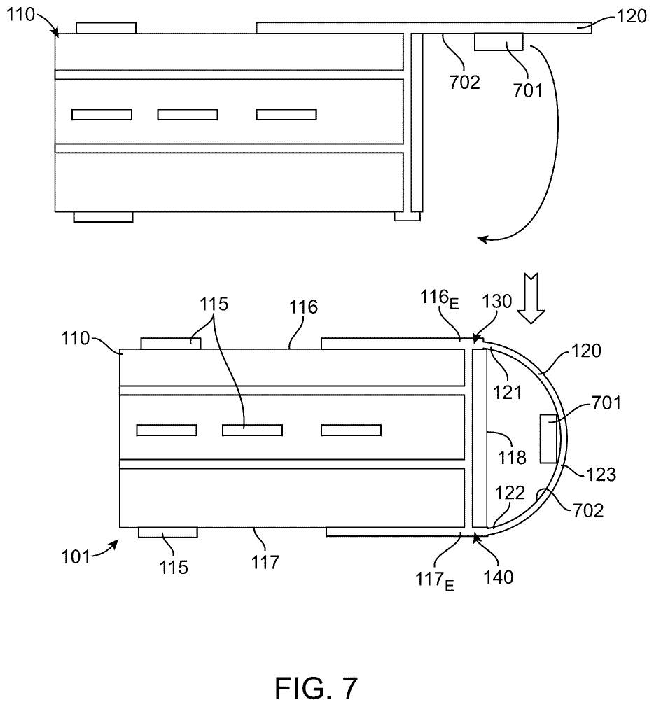

With continued reference to FIGS. 1, 2A, 2B and 3 and with additional reference to FIG. 7, the printed wiring substrate assembly 101 can further include a component 701 that is mounted to a surface 702 of the elongate foil portion 123 that faces the substrate edge surface 118. In these or other cases, the component 701 can include at least one of a direct current (DC) blocking cap, an oscillator and a wire-wound inductor.

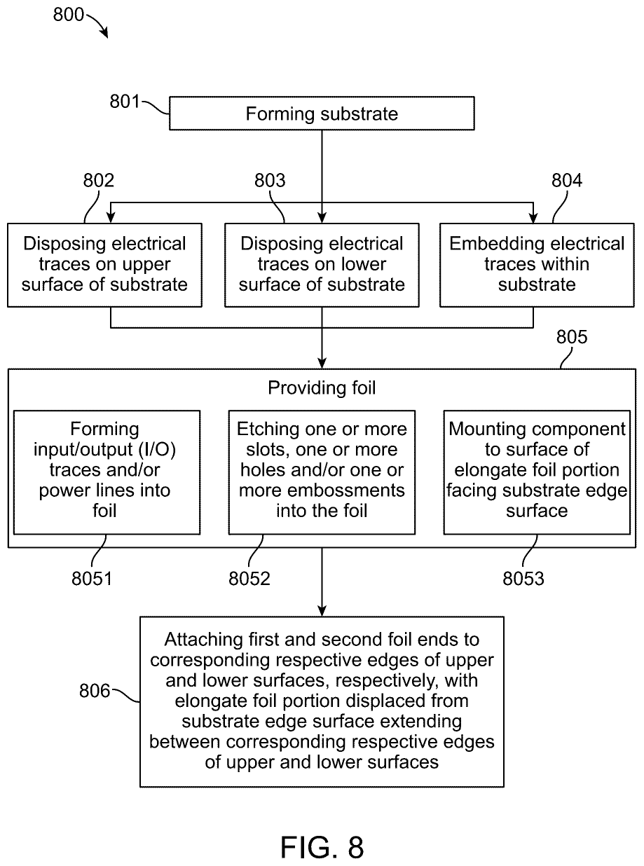

With reference to FIG. 8, a method 800 of fabricating a printed wiring substrate assembly, such as the printed wiring substrate assembly 101 of FIG. 1, is provided. The method 800 includes forming a substrate, such as the substrate 110 of FIG. 1 (block 801) and at least one of disposing electrical traces on an upper surface of the substrate (block 802), disposing electrical traces on a lower surface of the substrate (block 803) and embedding electrical traces within the substrate (block 804). The method 800 can further include providing a foil, such as the foil 120 of FIG. 1 (block 805) and attaching the first and second foil ends to corresponding respective edges of the upper and lower surfaces, respectively, with the elongate foil portion displaced from a substrate edge surface extending between the corresponding respective edges of the upper and lower surfaces (block 806). In accordance with one or more embodiments, the method 800 and/or the providing of the foil of block 804 can also include at least one of forming at least one of input/output (I/O) traces and power lines into the foil (block 8051), etching at least one of one or more slots, one or more holes and one or more embossments into the foil (block 8052) and mounting a component to a surface of the elongate foil portion facing the substrate edge surface (block 8053) where the component can include at least one of a DC blocking cap, an oscillator and a wire-wound inductor.

In accordance with one or more embodiments, the method 800 of FIG. 8 can be executed in detail as follows. First, a PCB clad is rendered with a copper foil extending beyond the bounds of the dielectric core by about 2-3 mm on all sides. The PCB clad is etched per normal PCB manufacturing processes to produce circuit patterns on both copper layers. A PCB composite (stack) is built up and includes multiple clads and pre-preg layers with the modified (overhanging) clad on the bottom or top of the composite stack so that the extended foil is the bottommost or topmost layer of the PCB. On each edge of the PCB clad, the foil overhang is pressed up or down to cover the exposed PCB edge. This can be accomplished manually, or using existing automated laminate press tooling. The foil is then attached to a copper border on the opposite side of the PCB by soldering or a mechanical attachment mechanism.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A printed wiring substrate assembly, comprising:
a substrate comprising electrical traces, an upper surface, a lower surface opposite the upper surface and a substrate edge surface extending between corresponding respective edges of the upper and lower surfaces;
a foil comprising a first foil end, a second foil end opposite the first foil end and an elongate foil portion extending between the first and second foil ends; and
first and second attachments at which the first and second foil ends are attached to the corresponding respective edges of the upper and lower surfaces, respectively, with the elongate foil portion displaced from the substrate edge surface.

2. The printed wiring substrate assembly according to claim 1, wherein:
the substrate is at least one of a single-layer printed circuit board (PCB) and a multi-layer PCB comprising multiple PCB layers laminated together, and
the electrical traces are at least one of disposed on the upper surface, disposed on the lower surface and embedded within the substrate.

3. The printed wiring substrate assembly according to claim 1, wherein elongate foil portion is displaced from the substrate edge surface by a distance that is a fraction of a thickness of the substrate.

4. The printed wiring substrate assembly according to claim 1, wherein the foil is continuous along an entirety of the substrate edge surface.

5. The printed wiring substrate assembly according to claim 4, wherein the foil is formed to define at least one of one or more slots for slot antennae, one or more holes for moisture, chemical and/or gaseous outflows and one or more embossments for quick response (QR) coding and/or barcoding.

6. The printed wiring substrate assembly according to claim 1, wherein the foil comprises at least one of metallic material and a copper clad plane pair.

7. The printed wiring substrate assembly according to claim 1, wherein the first and second attachments comprise at least one of conductive adhesive, solder, mounting screws and clamps.

8. The printed wiring substrate assembly according to claim 1, wherein the foil comprises at least one of input/output (I/O) traces and power lines.

9. The printed wiring substrate assembly according to claim 1, wherein:
the printed wiring substrate assembly further comprises a component mounted to a surface of the elongate foil portion facing the substrate edge surface, and
the component comprises at least one of a direct current (DC) blocking cap, an oscillator and a wire-wound inductor.

10. A printed wiring substrate assembly, comprising:
a substrate comprising electrical traces, an upper surface, a lower surface opposite the upper surface and first and second substrate edge surfaces forming a corner and respectively extending between corresponding respective edges of the upper and lower surfaces;
first and second foils respectively associated with the first and second substrate edges and each comprising a first foil end, a second foil end opposite the first foil end and an elongate foil portion extending between the first and second foil ends; and
first and second attachments for each of the first and second foils at which the respective first and second foil ends are attached to the corresponding respective edges of the upper and lower surfaces, respectively, with the respective elongate foil portions displaced from the first and second substrate edge surfaces.

11. The printed wiring substrate assembly according to claim 10, wherein:
the substrate is at least one of a single-layer printed circuit board (PCB) and a multi-layer PCB comprising multiple PCB layers laminated together, and
the electrical traces are at least one of disposed on the upper surface, disposed on the lower surface and embedded within the substrate.

12. The printed wiring substrate assembly according to claim 10, wherein the respective elongate foil portions are displaced from the first and second substrate edge surfaces by distances that are fractions of a thickness of the substrate.

13. The printed wiring substrate assembly according to claim 10, wherein the first and second foils are each continuous along respective entireties of the first and second substrate edge surfaces and form a gap between proximal sides at the corner.

14. The printed wiring substrate assembly according to claim 13, wherein the foil is formed to define at least one of one or more slots for slot antennae, one or more holes for moisture, chemical and/or gaseous outflows and one or more embossments for quick response (QR) coding and/or barcoding.

15. The printed wiring substrate assembly according to claim 10, wherein each of the first and second foils comprises at least one of metallic material and a copper clad plane pair.

16. The printed wiring substrate assembly according to claim 10, wherein each of the first and second attachments for each of the first and second foils comprises at least one of conductive adhesive, solder, mounting screws and clamps.

17. The printed wiring substrate assembly according to claim 10, wherein each of the first and second foils comprises at least one of input/output (I/O) traces and power lines.

18. The printed wiring substrate assembly according to claim 10, wherein:
the printed wiring substrate assembly further comprises components mounted to surfaces of the respective elongate foil portions facing the first and second substrate edge surfaces, and
each of the components comprises at least one of a direct current (DC) blocking cap, an oscillator and a wire-wound inductor.

19. A method of fabricating a printed wiring substrate assembly, the method comprising:
forming a substrate;
at least one of disposing electrical traces on an upper surface of the substrate, disposing electrical traces on a lower surface of the substrate and embedding electrical traces within the substrate;
providing a foil comprising a first foil end, a second foil end opposite the first foil end and an elongate foil portion extending between the first and second foil ends; and
attaching the first and second foil ends to corresponding respective edges of the upper and lower surfaces, respectively, with the elongate foil portion displaced from a substrate edge surface extending between the corresponding respective edges of the upper and lower surfaces.

20. The method according to claim 19, further comprising at least one of:
forming at least one of input/output (I/O) traces and power lines along the foil;
etching at least one of one or more slots, one or more holes and one or more embossments into the foil; and
mounting a component to a surface of the elongate foil portion facing the substrate edge surface, the component comprising at least one of a direct current (DC) blocking cap, an oscillator and a wire-wound inductor.
